(19) United States
(12) Patent Application Publication
(10) Pub. No.: US 2024/0249954 A1
(43) Pub. Date: Jul. 25, 2024

(54) IN SITU DAMAGE FREE ETCHING OF Ga2O3 USING Ga FLUX FOR FABRICATING HIGH ASPECT RATIO 3D STRUCTURES

(71) Applicant: OHIO STATE INNOVATION FOUNDATION, Columbus, OH (US)

(72) Inventors: Nidhin Kurian KALARICKAL, Columbus, OH (US); Andreas Fiedler, Columbus, OH (US); Siddharth Rajan, Columbus, OH (US)

(21) Appl. No.: 18/560,422

(22) PCT Filed: Mar. 14, 2022
(86) PCT No.: PCT/US2022/020143

§ 371 Date: Nov. 13, 2023

Related U.S. Application Data
(60) Provisional application No. 63/188,005, filed on May 13, 2021.

(51) Int. Cl. H01L 21/311; H01L 21/308; H01L 21/8234; H01L 29/20

(52) U.S. Cl. CPC H01L 21/31144; H01L 21/3081; H01L 21/31116; H01L 21/823431; H01L 29/2003

(57) ABSTRACT

A method for using gallium beam flux in an ultra-low vacuum environment to etch Ga2O3 epilayer surfaces is provided. An Ga2O3 epilayer surface (105) is patterned by applying a SiO2 mask (107) that corresponds to a desired structure (810). The patterned surface is then placed in an ultra-low vacuum environment (130) and is heated to a very high temperature (820; 830). At the same time, a gallium flux is supplied to the patterned surface in the ultra-low vacuum environment (840). The gallium flux causes etching in the patterned surface that is not covered by the SiO2 mask. Using this method, sub-micron (˜100 nm) three-dimensional (3D) structures like fins, trenches, and nano-pillars can be fabricated with vertical sidewalls.

### CROSS-REFERENCE TO RELATED APPLICATIONS

This application claims the benefit of U.S. provisional patent application No. 63/188,005, filed on May 13, 2021, and entitled “IN SITU DAMAGE FREE ETCHING OF Ga₂O₃ USING Ga FLUX FOR FABRICATING HIGH ASPECT RATIO 3D STRUCTURES,” the disclosure of which is expressly incorporated herein by reference in its entirety.

### STATEMENT OF GOVERNMENT SUPPORT

This invention was made with government support under grant/contract number FA9550-18-1-0479 awarded by the Air Force Office of Scientific Research. The government has certain rights in the invention.

### BACKGROUND

The ultra-wide bandgap semiconductor, β-Ga₂O₃, has attracted much interest owing to its large breakdown field strength of 8 MV/cm when compared to existing state-of-the-art technologies, like Si, SiC, and GaN. The high breakdown field strength theoretically predicts better performance for β-Ga₂O₃ based devices especially for applications, like high voltage switching and high frequency power amplification. In addition, the availability of bulk substrates grown from melt based techniques and the wide range of controllable doping (10¹⁵ to 10²⁰ cm⁻³) has led to rapid development of β-Ga₂O₃ devices in both vertical and lateral topologies with excellent performance.

Due to the lack of p-type doping, most vertical devices in β-Ga₂O₃ require confined and scaled regions that control the flow of current between the source and drain, like vertical fins and pillars. Using vertical fin structures also improves the electric field distribution in vertical Schottky barrier diodes by reducing the electric field seen at the Schottky metal semiconductor interface.

In addition, moving to a fin geometry would also result in increased power density and possibly enhancement-mode operation in lateral devices. Fabrication of these three-dimensional (3D) structures require controlled, damage-free etching that ideally provides vertical sidewalls (90° sidewall angle). Most dry etching recipes for etching β-Ga₂O₃ are based on chlorine and argon and have been found to cause significant etch damage resulting in nonideal device characteristics. Wet etching recipes have also been demonstrated using HF, H₃PO₄ (hot), and KOH (hot), but wet etching generally provides slanted sidewalls and poorly controlled etch depths, which are not ideal for fabricating scaled submicrometer fins. In addition to traditional dry and wet etching techniques, metal assisted chemical etching (MacEtch) for β-Ga₂O₃ was also demonstrated to produce 3D fin structures. However, the MacEtch process was found to result in slanted sidewalls along with reduced Schottky barrier heights on etched sidewalls.

It is with respect to these and other considerations that the various aspects and embodiments of the present disclosure are presented.

### SUMMARY

A method for using gallium (Ga) beam flux in an ultra-low vacuum environment to etch Ga₂O₃ epilayer surfaces is provided. An Ga₂O₃ epilayer surface is patterned by applying a SiO₂ mask that corresponds to a desired structure. The patterned surface is then placed in an ultra-low vacuum environment and is heated to a very high temperature. At the same time, a gallium flux is supplied to the pattern surface in the ultra-low vacuum environment. The gallium flux causes etching in the patterned surface that is not covered by the SiO₂ mask. Using this method, sub-micron (˜100 nm) three-dimensional (3D) structures like fins, trenches, and nano-pillars can be fabricated with vertical sidewalls.

In an implementation, a method comprises: patterning a Ga₂O₃ epilayer surface according to a desired structure; placing the patterned Ga₂O₃ epilayer surface into a vacuum environment; heating the patterned Ga₂O₃ epilayer surface in the vacuum environment to a temperature; and supplying a Ga flux to the patterned Ga₂O₃ epilayer surface for an amount of time to etch the desired structure into the Ga₂O₃ epilayer surface.

In an implementation, a system comprises: a vacuum environment; a gallium source; and a patterning device, wherein the patterning device is adapted to pattern a Ga₂O₃ epilayer surface according to a desired structure; wherein the vacuum environment is adapted to receive the patterned Ga₂O₃ epilayer surface; and heat the patterned Ga₂O₃ epilayer surface to a desired temperature; and wherein the gallium source is adapted to supply a Ga flux to the patterned Ga₂O₃ epilayer surface for an amount of time to etch the Ga₂O₃ epilayer surface.

This summary is provided to introduce a selection of concepts in a simplified form that are further described below in the detailed description. This summary is not intended to identify key features or essential features of the claimed subject matter, nor is it intended to be used to limit the scope of the claimed subject matter.

### BRIEF DESCRIPTION OF THE DRAWINGS

The foregoing summary, as well as the following detailed description of illustrative embodiments, is better understood when read in conjunction with the appended drawings. For the purpose of illustrating the embodiments, there is shown in the drawings example constructions of the embodiments; however, the embodiments are not limited to the specific methods and instrumentalities disclosed. In the drawings:

FIG. 1 is an illustration of an example environment for etching one or more Ga₂O₃ epilayer surfaces;

FIG. 2 is an illustration of an example etched surface with a fin structure;

FIG. 3 is an illustration of an example etched surface showing vertical etching;

FIG. 4 is an illustration of an example etched surface showing vertical etching with an etch stop layer;

FIG. 5 is an illustration of an etched surface with one or more undercut structures;

FIG. 6 is an illustration of an etched surface using multiple etch stop layers to create multiple undercut structures;

FIG. 7 is an illustration of an etched surface using masks to prevent vertical etching; and

FIG. 8 is an illustration of an example method for etching a Ga₂O₃ surface.

### DETAILED DESCRIPTION

The following description of the disclosure is provided as an enabling teaching of the disclosure in its best, currently known embodiment(s). To this end, those skilled in the relevant art will recognize and appreciate that many changes can be made to the various embodiments of the invention described herein, while still obtaining the beneficial results of the present disclosure. It will also be apparent that some of the desired benefits of the present disclosure can be obtained by selecting some of the features of the present disclosure without utilizing other features. Accordingly, those who work in the art will recognize that many modifications and adaptations to the present disclosure are possible and can even be desirable in certain circumstances and are a part of the present disclosure. Thus, the following description is provided as illustrative of the principles of the present disclosure and not in limitation thereof.

Unless defined otherwise, all technical and scientific terms used herein have the same meaning as commonly understood to one of ordinary skill in the art to which this invention belongs. As used in the specification and claims, the singular form “a,” “an,” and “the” include plural references unless the context clearly dictates otherwise. As used herein, the terms “can,” “may,” “optionally,” “can optionally,” and “may optionally” are used interchangeably and are meant to include cases in which the condition occurs as well as cases in which the condition does not occur. Reference in the specification to “one embodiment” or “an embodiment” or “an example embodiment” means that a particular feature, structure, or characteristic described is included in at least one embodiment described herein and does not imply that the feature, structure, or characteristic is present in all embodiments described herein. Publications cited herein are hereby specifically incorporated by reference in their entireties and at least for the material for which they are cited.

Ranges can be expressed herein as from “about” one particular value, and/or to “about” another particular value. When such a range is expressed, another embodiment includes from the one particular value and/or to the other particular value. Similarly, when values are expressed as approximations, by use of the antecedent “about,” it will be understood that the particular value forms another embodiment. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed.

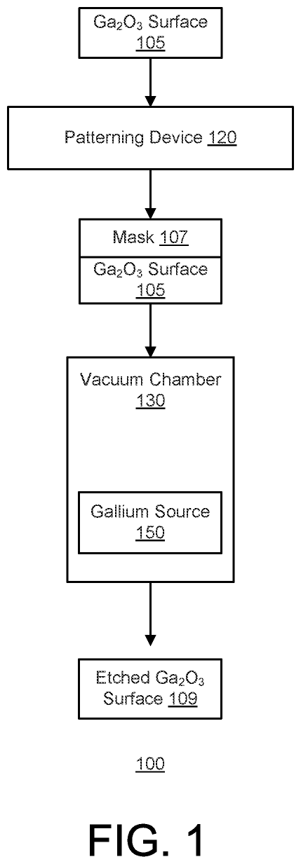

FIG. 1 is an illustration of an example environment 100 for etching one or more Ga₂O₃ epilayer surfaces 105. In the examples described herein, the surface 105 is a β-Ga₂O₃ epilayer surface 105, however other types of surfaces 105 may be used including other polymorphs of Ga₂O₃ like α, γ, ∈, and κ.

The environment 100 may include a patterning device 120 that is configured to apply a mask 107 to the surface 105 in a pattern that corresponds to a desired structure that is to be etched into the surface 105. Example structures include fins, trenches, nano pillars, and sidewalls. The etched surfaces 105 may then be used as components in one or more devices such as vertical trench MOSFETs, vertical Schottky barrier diodes, lateral fin transistors, and field emission devices. Other uses for etching include increasing a surface concentration of dopants in the surface 105.

In some embodiments, the mask 107 may be a SiO₂ mask 107 and may be approximately 100 nm thick. Other thicknesses may be supported. The patterning device 120 may pattern or apply the mask 107 to the surface 105 using plasma enhanced chemical vapor deposition. Alternatively, the patterning device 120 may apply the mask 107 using optical lithography. Other methods may be used.

After the mask 107 is applied to the surface 105, the surface 105 may be placed into a vacuum chamber 130. The vacuum chamber 130 may be a high vacuum chamber including a molecular beam epitaxy (MBE) chamber such as the Veeco™ Gen 930. Other chambers may be used. The vacuum chamber 130 may be free from oxygen or other gasses and may be capable of heating the surface 105 to a very high temperature, such as between 500 C and 800 C. Other temperatures may be supported. The vacuum chamber 130 may include a sample holder that can heat and rotate the Ga₂O₃ sample.

The vacuum chamber 130 may include a gallium source 150. The gallium source 150 may output or supply a Ga flux towards the surface 105 in the vacuum chamber 130. Depending on the embodiment, the gallium source 150 may supply a Ga flux ranging between 1.5×10⁻⁷ to 1.3×10⁻⁶ Torr. Other flux ranges may be used.

As may be appreciated, in β-Ga₂O₃, epitaxial growth proceeds via competition between sesquioxide (Ga₂O₃) and the suboxide phases (Ga₂O). In the absence of active oxygen, as in the vacuum chamber 130, exposure of the Ga₂O₃ surface 105 to Ga flux results in etching of the surface 105 according to the following equation 1:

$$4 Ga ( s ) + {Ga}_{2} {O}_{3} ( s ) \to 3 {Ga}_{s} O ( g )$$

Accordingly, the surface 105 may be etched by the Ga flux output by the gallium source 150 while in the vacuum chamber 130. In some embodiments, the surface 105 may be rotated in the vacuum chamber 130 to ensure that the Ga flux is received evenly by the surface 105.

Portions of the surface 105 may be protected from the etching by the mask 107 applied by the patterning device 120. Thus, an administrator or a user may select a size and shape of the mask 107 based on a desired structure to be etched into the surface 105. The surface 105 after being subjected to the etching by the gallium source 150 is referred to as the etched surface 109.

In addition to the mask 107, the size and shape of the structure that is etched into the surface 105 may be controlled by adjusting a variety of factors. These factors include one or both of an angle of rotation of the surface 105 in the vacuum chamber 130 or an angle at which the gallium source 150 is mounted in the vacuum chamber 130, an amount of time that the surface 105 is subjected to the Ga flux in the chamber 130, a strength of the Ga flux, and the temperature of the vacuum chamber 130.

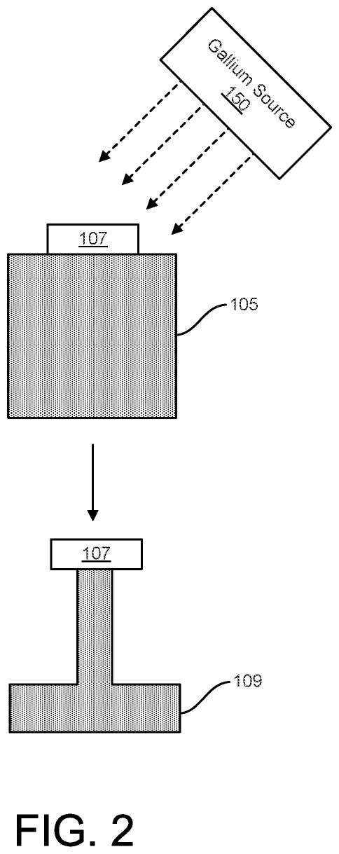

In the example structures 105 of FIGS. 2-7, the exposed β-Ga₂O₃ surface 105 gets etched down according to the equation 1 given above at an etch rate of A (nm/min). In addition to the vertical etching, the sidewalls are etched inwards at a rate of (A (nm/min), where (is the ratio of lateral to vertical etch rate. Preliminary experiments shows that the value of (is between 0.1 and 0.3 at a substrate temperature of 700 C, depending on the orientation of the pattern on the β-Ga₂O₃ surface 105. The lateral etching is also found to maintain vertical sidewalls. The lateral etching that maintains vertical sidewall profile is a unique advantage of this method and helps in reducing the feature size to submicron values.

In some embodiments, the etching rates may be between 2.9 and 30 nm/min. The etching rate may be proportional to the supplied Ga flux. Experiments have shown that etch rates below 10 nm/min may be suitable for processes such as gate recess and regrowth etching, and etch rates around 30 nm/min may be suitable for deep etching to fabricate structures such as fins and trenches.

FIG. 2 is an illustration of an example etched surface 109 with a fin structure. In the example shown, a surface 105 is prepared with a mask 107 by the patterning device 120. The example mask 107 leaves areas on the left and right side of the surface 105 exposed.

The surface 105 is placed in the vacuum chamber 130 and receives a Ga flux (represented by the hashed arrows) from the gallium source 150. While the Ga flux is received, the chamber 130 is heated to between 500 C and 800 C, and the surface 105 is spun around its vertical axis.

The etched surface 109 shows the result of the etching process. In the example shown, the portions of the surface 109 that were shielded by the mask 107 remain in the surface 109, while the portions of the surface 109 that were not shielded have been etched away leavening a column or fin structure. The amount of vertical etching vs. lateral etching may be controlled by the angle of the Ga flux received by the surface 109.

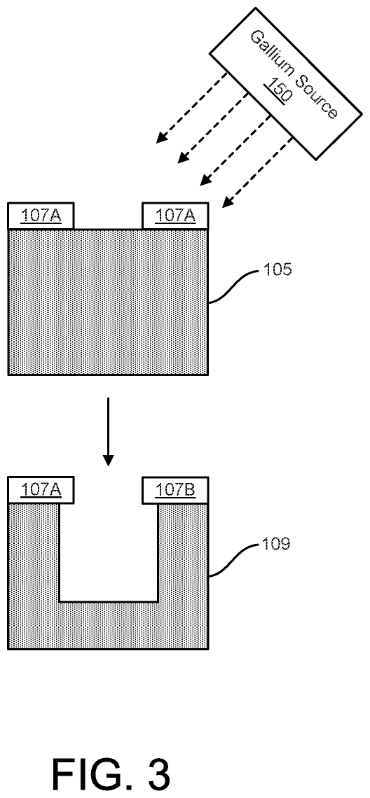

FIG. 3 is an illustration of an example etched surface 109 showing vertical etching. In the example shown, a surface 105 is prepared with a mask 107 that includes two parts shown as the mask 107A and the mask 107B. The masks 107A and 107B are arranged so that a space to receive the Ga flux is created between the masks 107A and 107B.

The example etched surface 109 shows the result of the vertical etching process. In the example shown, the portions of the surface 109 that were shielded by the mask 107A and 107B remain in the surface 109, while the portions of the surface 109 that were not shielded have been etched away leavening a recessed hole in the surface 109. Note that there is lateral etching underneath the masks 107A and 107B due to the angle of the Ga flux. The amount of lateral etching can be increased or decreased by adjusting the angle of the Ga flux. The surface 109 with vertical etching of FIG. 3 could be used for applications such as gate recess and etch regrowth, for example.

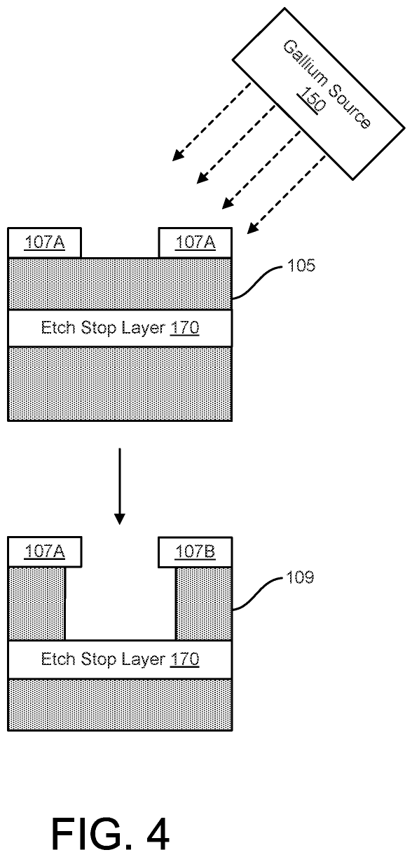

FIG. 4 is an illustration of an example etched surface 109 showing vertical etching with an etch stop layer 170. The etch stop layer 170 may be a layer of a material that resists the etching from the Ga flux. The etch stop layer 170 is similar to the mask 107, but may be placed within the surface 105, rather than on the top of the surface 105. A suitable material for the etch stop layer 170 is β-(AlₓGa₁₋ₓ)₂O₃. Other types of materials may be supported.

As shown in the etched surface 109 of FIG. 4, the etch stop layer 170 has effectively stopped any further vertical etching in the etched surface 109. Because of the angle of the Ga flux, no further lateral etching is shown.

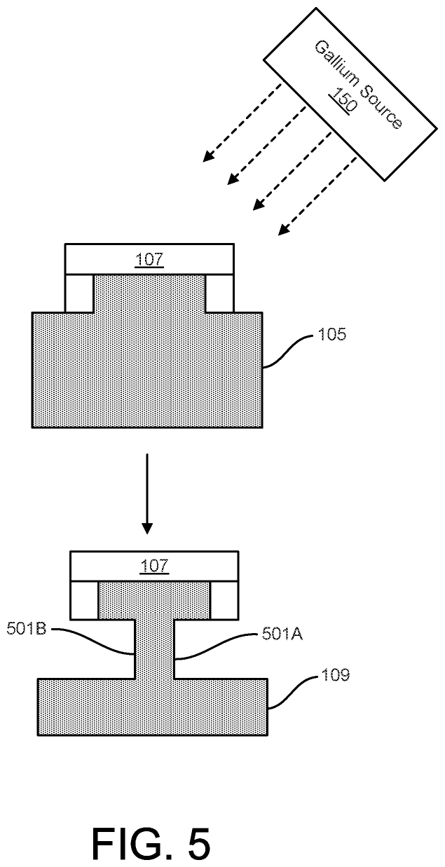

FIG. 5 is an illustration of an etched surface 109 with one or more undercut structures 501 (i.e., the undercut structures 501A and 501B). In the example shown, the surface 105 includes a protrusion over which the patterning device 120 deposits the mask 107.

After the etching process in the vacuum chamber, the resulting etched surface 109 includes two undercut structures 501 caused by the lateral and vertical etching. Because the mask 170 covered much of the surface 109, the resulting etching is mostly lateral etching. The ratio of lateral to vertical etching that defines the dimensions of the undercut structures 501 may be adjusted by changing the angle of the Ga flux, the size of the mask 107, and the size of the protrusion of the surface 105.

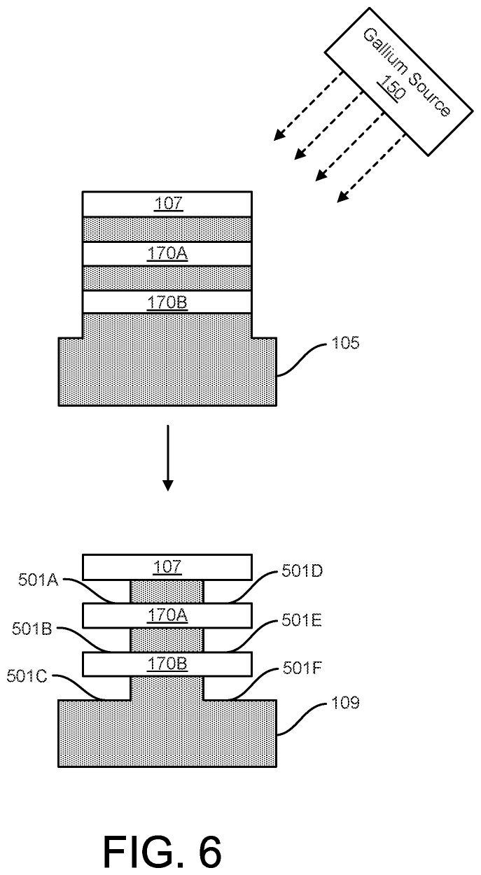

FIG. 6 is an illustration of an etched surface 109 using multiple etch stop layers 170 to create multiple undercut structures 501. Similar to the example of FIG. 5, the structure 105 includes a protrusion over which the mask 107 is deposited. However, unlike the example of FIG. 5, the mask 107 does not extend over the sides of the protrusion and two etch stop layers 170 (i.e., the layers 107A and 170B) have been inserted into the protrusion of the surface 105.

After the etching process in the vacuum chamber 130, the resulting etched surface 109 includes six undercuts 501 (i.e., the undercuts 501A-501F) caused by the lateral etching. The regions of the surface 109 that were not covered by the mask 107 show vertical etching. Because the mask 170 covered much of the surface 109, the resulting etching is mostly lateral etching. The amount of lateral etching used to form the undercuts 501 may be adjusted by changing the angle of the Ga flux, the size of the mask 107, and the size of the protrusion of the surface 105.

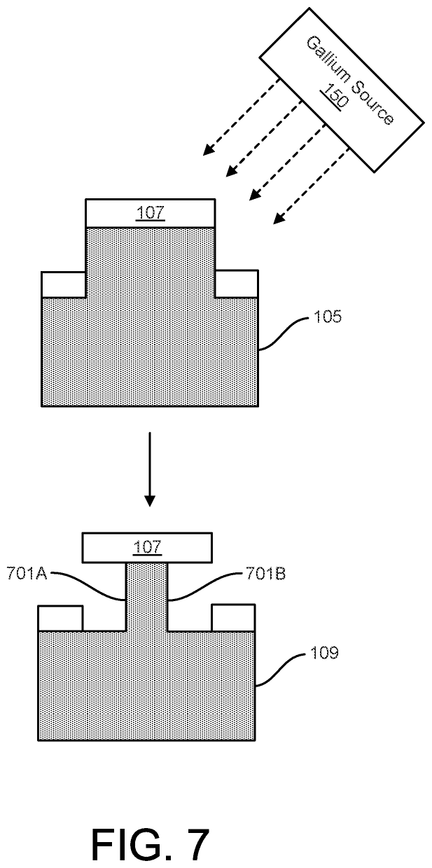

FIG. 7 is an illustration of an etched surface 109 using masks to prevent vertical etching. Similar to the example of FIG. 5, the structure 105 includes a protrusion. However, unlike the example of FIG. 5, the mask 107 is only applied to horizontal surfaces of the surface 105.

After the etching process in the vacuum chamber 130, the resulting etched surface 109 includes two vertical sidewalls 701A and 701B caused by the lateral etching. The amount of lateral etching used to form the sidewalls 710 may be adjusted by changing the angle of the Ga flux and the size of the protrusion of the surface 105.

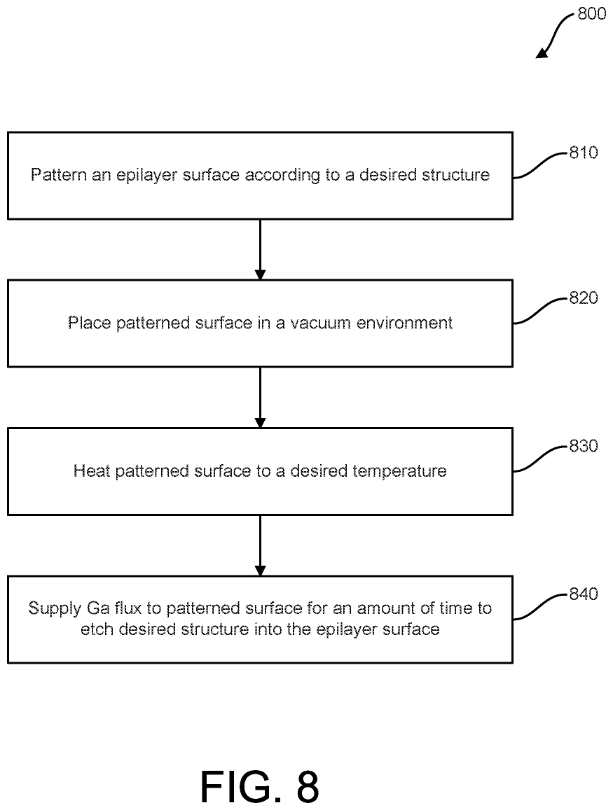

FIG. 8 is an illustration of an example method 800 for etching a Ga₂O₃ surface. The method 800 may be implemented using one or more of a patterning device 120, a vacuum chamber 130, a sample holder that can heat and rotate the Ga₂O₃ sample and a gallium source 150.

At 810, an epilayer surface is patterned according to a desired structure. The epilayer surface 105 may be a Ga₂O₃ surface and may be patterned by a patterning device 120. The pattern may be a mask 107 that is applied to the surface 105 using one or more of plasma enhanced chemical vapor deposition and optical lithography. Depending on the embodiment, the mask 107 may be an SiO₂ mask 107. The desired structure may include fins, trenches, nano pillars, and sidewalls.

At 820, the patterned surface is placed in a vacuum environment. The vacuum environment may be the vacuum chamber 130. The vacuum chamber may be an MBE chamber, for example. The vacuum chamber 130 may be an oxygen free environment and may include a gallium source 150.

At 830, the patterned surface is heated to a desired temperature. The patterned surface 105 may be heated by the vacuum chamber 130 to a temperature of between approximately 500 C to 800 C.

At 840, a Ga flux is supplied to the patterned surface for an amount of time to etch the desired structure into the epilayer surface. The Ga flux may be supplied by the gallium source 150. The amount of time and strength may be based on the dimensions of the desired structure and a lateral and vertical etch rate of the Ga flux. After the etching is completed, the mask 107 may be removed from the etched surface 109, and the etched surface may be used in one or more devices including vertical trench MOSFETs, vertical Schottky barrier diodes, lateral fin transistors, and field emission devices.

In an implementation, a method comprises: patterning a Ga₂O₃ epilayer surface according to a desired structure; placing the patterned Ga₂O₃ epilayer surface into a vacuum environment; heating the patterned Ga₂O₃ epilayer surface in the vacuum environment to a temperature; and supplying a Ga flux to the patterned Ga₂O₃ epilayer surface for an amount of time to etch the desired structure into the Ga₂O₃ epilayer surface.

Implementations may include some or all of the following features. Patterning the Ga₂O₃ epilayer surface comprises patterning the epilayer surface using SiO₂. Patterning the Ga₂O₃ epilayer surface comprises patterning the epilayer surface using optical lithography or plasma enhanced chemical vapor deposition. The etching the Ga₂O₃ epilayer surface increases a concentration of dopants in the Ga₂O₃ epilayer surface. The vacuum environment comprises a molecular beam epitaxy (MBE) chamber. The method further comprises rotating the patterned Ga₂O₃ surface while supplying the Ga flux to the patterned Ga₂O₃ epilayer surface. The method further comprises rotating the patterned Ga₂O₃ surface about an angle while supplying the Ga flux to the patterned Ga₂O₃ epilayer surface. The desired structure comprises one or more vertical sidewalls, one or more undercut structures, and one or more fins. The Ga₂O₃ epilayer surface comprises a β-Ga₂O₃ surface. The Ga₂O₃ epilayer surface further comprises an etch stop layer. The etch stop layer comprises β-(AlₓGa₁₋ₓ)₂O₃.

In an implementation, a system comprises: a vacuum environment; a gallium source; and a patterning device, wherein the patterning device is adapted to pattern a Ga₂O₃ epilayer surface according to a desired structure; wherein the vacuum environment is adapted to receive the patterned Ga₂O₃ epilayer surface; and heat the patterned Ga₂O₃ epilayer surface to a desired temperature; and wherein the gallium source is adapted to supply a Ga flux to the patterned Ga₂O₃ epilayer surface for an amount of time to etch the Ga₂O₃ epilayer surface.

Implementations may include some or all of the following features. The patterning device is adapted to pattern the Ga₂O₃ epilayer using SiO₂. The patterning device is adapted to pattern the Ga₂O₃ epilayer using optical lithography. The vacuum environment comprises a molecular beam epitaxy (MBE) chamber. The desired structure comprises one or more vertical sidewalls, one or more undercut structures, and one or more fins. The Ga₂O₃ epilayer surface comprises a β-Ga₂O₃ surface. The Ga₂O₃ epilayer surface further comprises an etch stop layer. The etch stop layer comprises β-(AlₓGa₁₋ₓ)₂O₃. The vacuum environment is further adapted to rotate the Ga₂O₃ epilayer surface while Ga flux is applied.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

What is claimed:

1. A method comprising:
patterning a Ga₂O₃ epilayer surface according to a desired structure;
placing the patterned Ga₂O₃ epilayer surface into a vacuum environment;
heating the patterned Ga₂O₃ epilayer surface in the vacuum environment to a temperature; and
supplying a Ga flux to the patterned Ga₂O₃ epilayer surface for an amount of time to etch the desired structure into the Ga₂O₃ epilayer surface.

2. The method of claim 1, wherein patterning the Ga₂O₃ epilayer surface comprises patterning the epilayer surface using SiO₂.

3. The method of claim 1, wherein patterning the Ga₂O₃ epilayer surface comprises patterning the epilayer surface using optical lithography or plasma enhanced chemical vapor deposition.

4. The method of claim 1, wherein the etching the Ga₂O₃ epilayer surface increases a concentration of dopants in the Ga₂O₃ epilayer surface.

5. The method of claim 1, wherein the vacuum environment comprises a molecular beam epitaxy (MBE) chamber.

6. The method of claim 1, further comprising rotating the patterned Ga₂O₃ surface while supplying the Ga flux to the patterned Ga₂O₃ epilayer surface.

7. The method of claim 1, further comprising rotating the patterned Ga₂O₃ surface about an angle while supplying the Ga flux to the patterned Ga₂O₃ epilayer surface.

8. The method of claim 1, wherein the desired structure comprises one or more vertical sidewalls, one or more undercut structures, and one or more fins.

9. The method of claim 1, wherein the Ga₂O₃ epilayer surface comprises a β-Ga₂O₃ surface.

10. The method of claim 1, wherein the Ga₂O₃ epilayer surface further comprises an etch stop layer.

11. The method of claim 10, wherein the etch stop layer comprises β-(AlₓGa₁₋ₓ)₂O₃.

12. A system comprising:
a vacuum environment;
a gallium source; and
a patterning device, wherein the patterning device is adapted to pattern a Ga₂O₃ epilayer surface according to a desired structure;
wherein the vacuum environment is adapted to receive the patterned Ga₂O₃ epilayer surface; and heat the patterned Ga₂O₃ epilayer surface to a desired temperature; and
wherein the gallium source is adapted to supply a Ga flux to the patterned Ga₂O₃ epilayer surface for an amount of time to etch the Ga₂O₃ epilayer surface.

13. The system of claim 12, wherein the patterning device is adapted to pattern the Ga₂O₃ epilayer using SiO₂.

14. The system of claim 12, wherein the patterning device is adapted to pattern the Ga₂O₃ epilayer using optical lithography.

15. The system of claim 12, wherein the vacuum environment comprises a molecular beam epitaxy (MBE) chamber.

16. The system of claim 12, wherein the desired structure comprises one or more vertical sidewalls, one or more undercut structures, and one or more fins.

17. The system of claim 12, wherein the Ga₂O₃ epilayer surface comprises a β-Ga₂O₃ surface.

18. The system of claim 12, wherein the Ga₂O₃ epilayer surface further comprises an etch stop layer.

19. The system of claim 12, wherein the etch stop layer comprises β-(AlₓGa₁₋ₓ)₂O₃.

20. The system of claim 12, wherein the vacuum environment is further adapted to rotate the Ga₂O₃ epilayer surface while Ga flux is applied.
